(19) United States
(12) Patent Application Publication
(10) Pub. No.: US 2025/0287690 A1
(43) Pub. Date: Sep. 11, 2025

(54) SEMICONDUCTOR DEVICE AND METHOD OF FABRICATING THE SAME

(71) Applicant: Samsung Electronics Co., Ltd., Suwon-si (KR)

(72) Inventors: Gukhee Kim, Suwon-si (KR); Junsun Hwang, Suwon-si (KR); Yuji Moon, Suwon-si (KR); Ra You, Suwon-si (KR); Kyoungwoo Lee, Suwon-si (KR); Seungseok Ha, Suwon-si (KR)

(21) Appl. No.: 18/967,972

(22) Filed: Dec. 4, 2024

(30) Foreign Application Priority Data
Mar. 8, 2024 (KR) 10-2024-0033491

(51) Int. Cl. H01L 21/02

(52) U.S. Cl. CPC H10D 84/851; H10D 30/0194; H10D 30/0197; H10D 30/0198; H10D 30/506; H10D 30/508; H10D 84/013; H10D 84/0142; H10D 84/0149; H10D 84/0153; H10D 84/8312; H10D 84/83138; H10D 84/832; H10D 89/611; H10D 89/10

(57) ABSTRACT

A semiconductor device may include a substrate, a lower power line in a lower portion of the substrate, metal layers on the substrate, and a protection structure that is electrically connected to the lower power line and the metal layers. The protection structure may include a doping pattern in the substrate, and a first source/drain pattern that is on the substrate and is electrically connected to an upper portion of the doping pattern. The doping pattern and the first source/drain pattern may include different dopants from each other.

### CROSS-REFERENCE TO RELATED APPLICATIONS

This U.S. non-provisional patent application claims priority under 35 U.S.C. § 119 to Korean Patent Application No. 10-2024-0033491, filed on Mar. 8, 2024, in the Korean Intellectual Property Office, the entire contents of which are hereby incorporated by reference.

### TECHNICAL FIELD

The present disclosure relates to semiconductor devices and methods of fabricating the same, and in particular, to semiconductor devices including field effect transistors and methods of fabricating the same.

### BACKGROUND

A semiconductor device includes an integrated circuit consisting of metal-oxide-semiconductor field-effect transistors (MOSFETs). To meet an increasing demand for a semiconductor device with a small pattern size and a reduced design rule, the size of the MOSFETs are being reduced. The reduced sizes of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY

Embodiments of the present disclosure provides a semiconductor device with improved electrical and reliability characteristics.

Embodiments of the present disclosure provides a method of fabricating a semiconductor device with improved electrical and reliability characteristics.

According to some embodiments of the present disclosure, a semiconductor device may include a substrate, a lower power line in a lower portion of the substrate, metal layers on the substrate, and a protection that is electrically connected to the lower power line and the metal layers. The protection structure may include a doping pattern in the substrate, and a first source/drain pattern that is on the substrate and is electrically connected to an upper portion of the doping pattern. The doping pattern and the first source/drain pattern may include different dopants from each other.

According to some embodiments of the present disclosure, a semiconductor device may include a first substrate including a first insulating pattern and a second insulating pattern, a lower power line in a lower portion of the first substrate, metal layers on the substrate, and a first protection structure on the first insulating pattern and a second protection structure on the second insulating pattern. The first protection structure and second protection structure may be electrically connected to the lower power line and the metal layers. The first protection structure may include a first doping pattern in the first insulating pattern and a first source/drain pattern on the first doping pattern, and the second protection structure may include a second doping pattern in the second insulating pattern and a second source/drain pattern on the second doping pattern. The first and second doping patterns may have different conductivity types from each other.

According to some embodiments of the present disclosure, a semiconductor device may include a first substrate including a first region and a second region, a channel pattern that is on a first surface of the first substrate and on the first region, wherein the channel pattern comprises a plurality of semiconductor patterns that are spaced apart from each other in a first direction that is perpendicular to an upper surface of the first substrate, a first source/drain pattern electrically connected to the channel pattern, a doping pattern on the second region, a second source/drain pattern on the doping pattern, a gate electrode on the channel pattern, a gate insulating layer between the gate electrode and the channel pattern, a gate spacer on a side surface of the gate electrode, a gate capping pattern on a top surface of the gate electrode, an interlayer insulating layer on the first source/drain pattern, the second source/drain pattern, and the gate capping pattern, a gate contact that extends into the interlayer insulating layer and the gate capping pattern and is electrically connected to the gate electrode, an active contact that extends into the interlayer insulating layer and is electrically connected to the second source/drain pattern, a plurality of metal layers on the interlayer insulating layer, where each of the plurality of metal layers includes interconnection lines and vias, a second substrate that is on the plurality of metal layers and includes an impurity region, a lower power line on a second surface of the first substrate that is opposite to the first surface of the first substrate, and a back-side contact that extends into the first region and electrically connects the lower power line to the first source/drain pattern. The second source/drain pattern may be electrically connected to the impurity region of the second substrate by the active contact and the plurality of metal layers.

### BRIEF DESCRIPTION OF THE DRAWINGS

FIGS. 1, 2, and 3 are conceptual diagrams illustrating logic cells of a semiconductor device, according to embodiments of the present disclosure.

FIG. 4 is a plan view illustrating a semiconductor device according to embodiments of the present disclosure.

FIGS. 5A, 5B, 5C, 5D, 5E, and 5F are sectional views taken along lines A-A′, B-B′, C-C′, D-D′, E-E′, and F-F′, respectively, of FIG. 4.

FIGS. 6A, 6B, 7A, 7B, 8A, 8B, 8C, 9A, 9B, 9C, 10A, 10B, 10C, 11A, 11B, 12A, 12B, 12C, 12D, 13A, 13B, 14A, 14B, 15A, and 15B are sectional views illustrating a method of fabricating a semiconductor device according to embodiments of the present disclosure.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection.

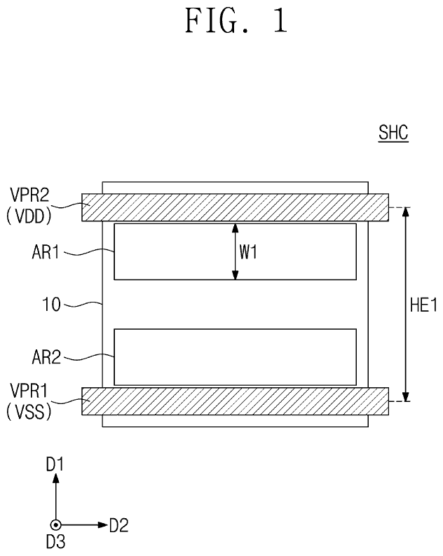

FIGS. 1 to 3 are conceptual diagrams illustrating logic cells of a semiconductor device, according to an embodiment of the present disclosure.

Referring to FIG. 1, a single height cell SHC may be provided. In detail, a first lower power line VPR1 and a second lower power line VPR2 may be provided below a main substrate 10. The first lower power line VPR1 may be a conduction path, to which a source voltage VSS (e.g., a ground voltage) is provided. The second lower power line VPR2 may be a conduction path, to which a drain voltage VDD (e.g., a power voltage) is provided.

The single height cell SHC may be defined between the first lower power line VPR1 and the second lower power line VPR2. The single height cell SHC may include one PMOSFET region AR1 and one NMOSFET region AR2. In other words, the single height cell SHC may have a CMOS structure provided between the first lower power line VPR1 and the second lower power line VPR2.

Each of the PMOSFET and NMOSFET regions AR1 and AR2 may have a first width W1 in a first direction D1. A length of the single height cell SHC in the first direction D1 may be defined as a first height HE1. The first height HE1 may be substantially equal to a distance (e.g., pitch) between the first lower power line VPR1 and the second lower power line VPR2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

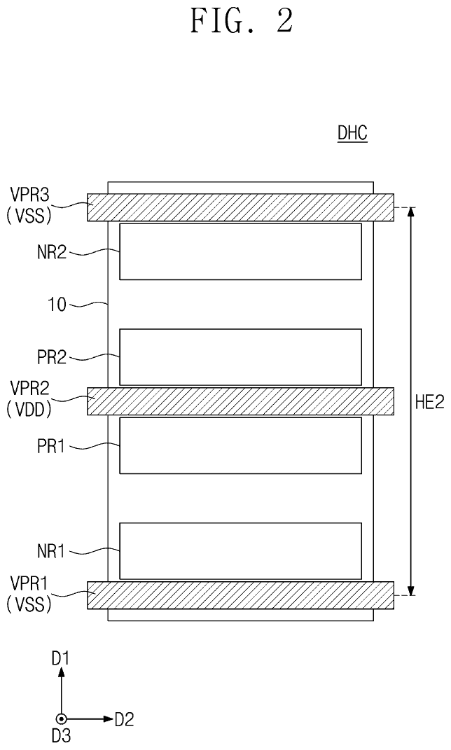

Referring to FIG. 2, a double height cell DHC may be provided. In detail, the first lower power line VPR1, the second lower power line VPR2, and a third lower power line VPR3 may be provided on the main substrate 10. The second lower power line VPR2 may be disposed between the first lower power line VPR1 and the third lower power line VPR3. The third lower power line VPR3 may be a conduction path, to which the source voltage VSS is provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A length of the double height cell DHC in the first direction D1 may be defined as a second height HE2. The second height HE2 may be about two times greater than the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times greater than the channel size of the PMOS transistor of the single height cell SHC. In this case, the double height cell DHC may be operated at a higher speed than the single height cell SHC. In some embodiments, the double height cell DHC shown in FIG. 2 may be defined as a multi-height cell. Although not shown, the multi-height cell may include a triple height cell whose cell height is about three times greater than that of the single height cell SHC.

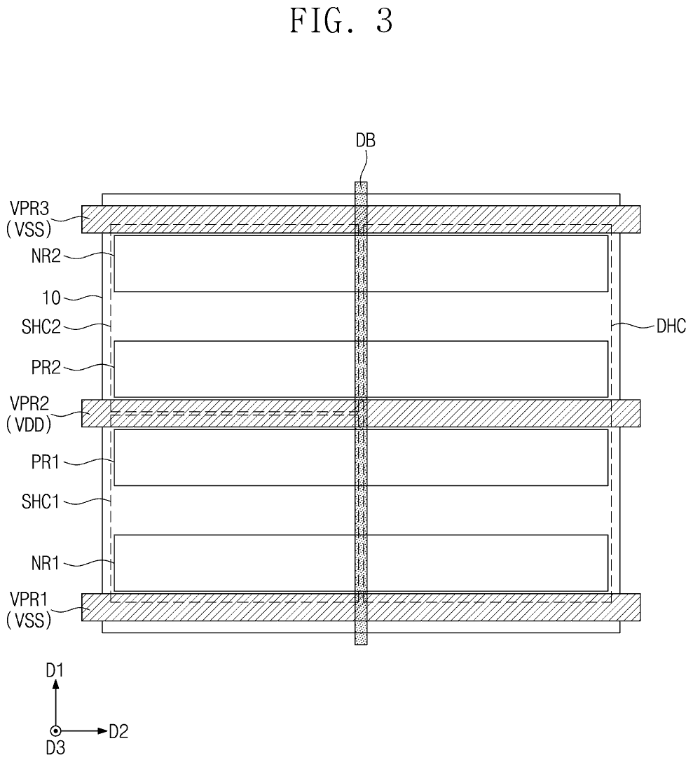

Referring to FIG. 3, a first single height cell SHC1, a second single height cell SHC2, and a double height cell DHC may be two-dimensionally arranged on the main substrate 10. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. An active region of the double height cell DHC may be electrically separated from an active region of each of the first and second single height cells SHC1 and SHC2 by the division structure DB.

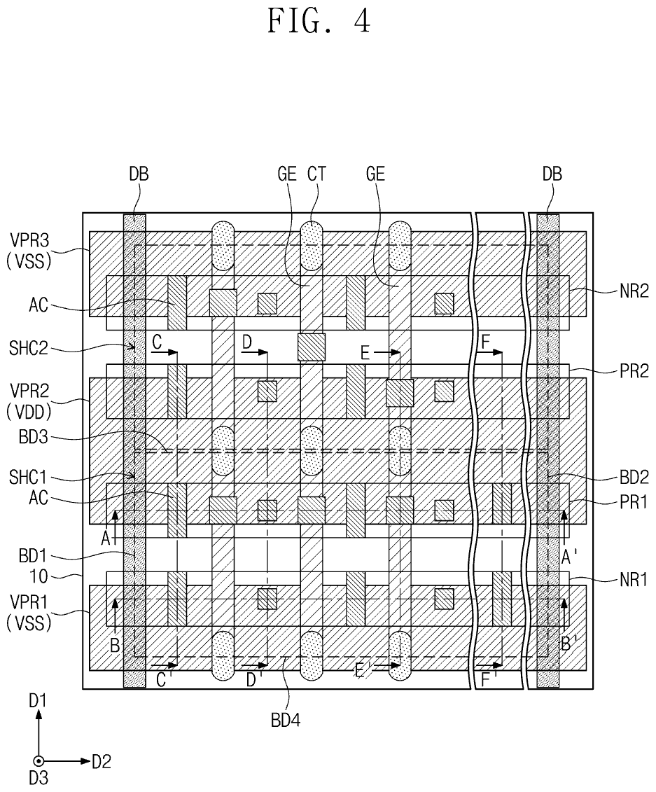

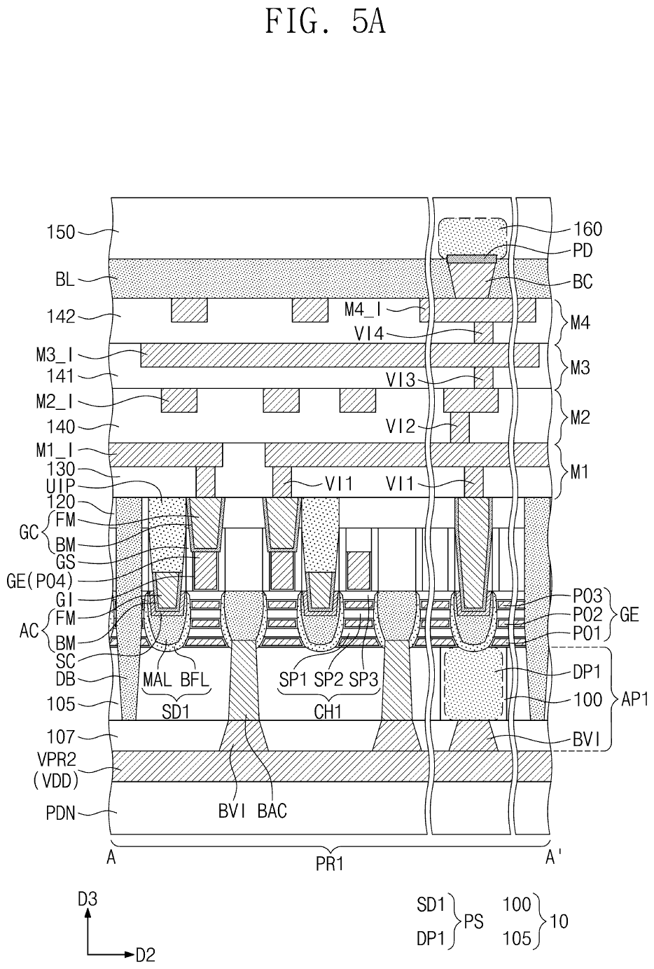

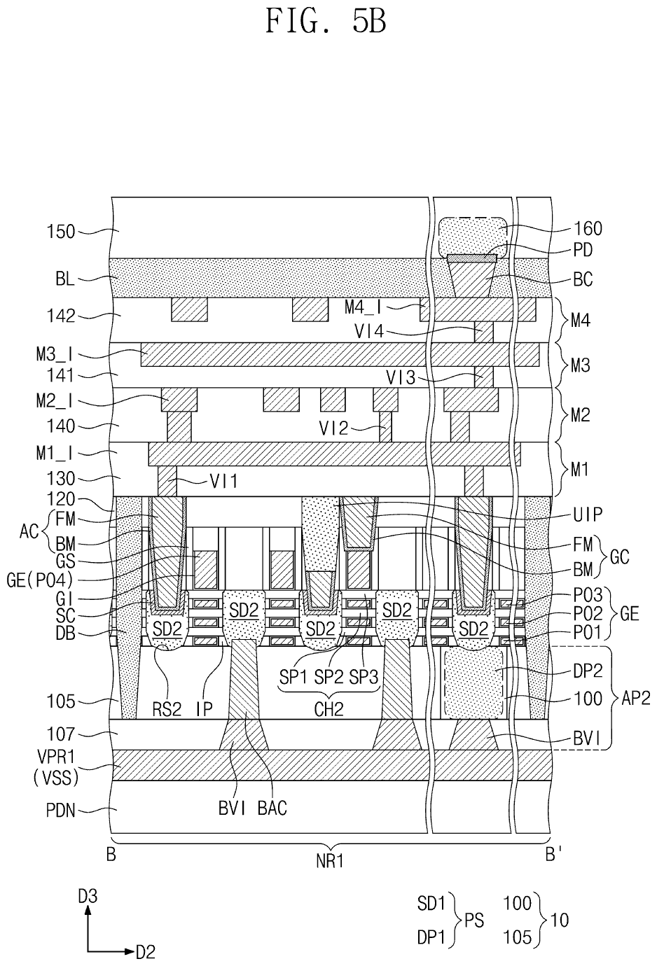

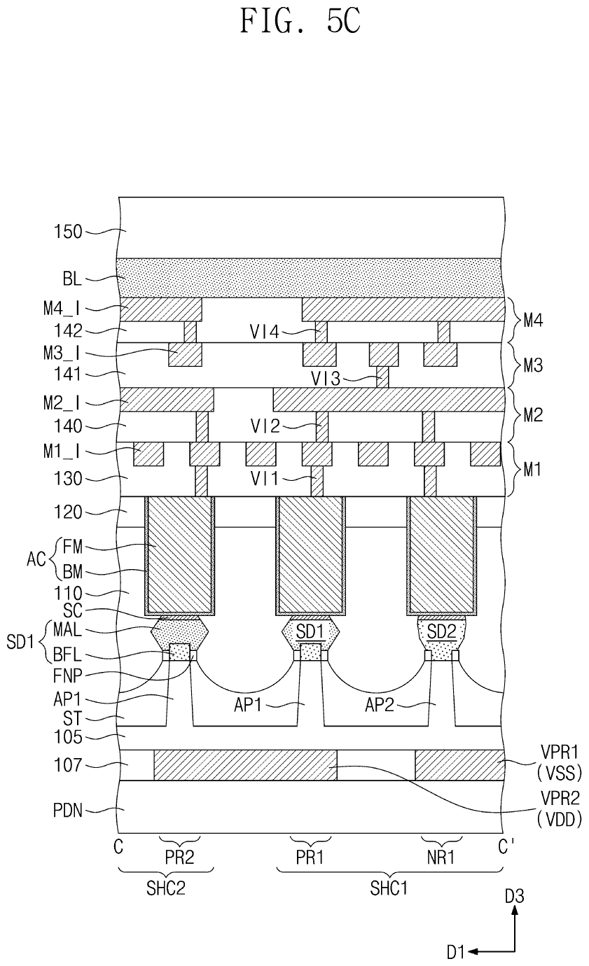

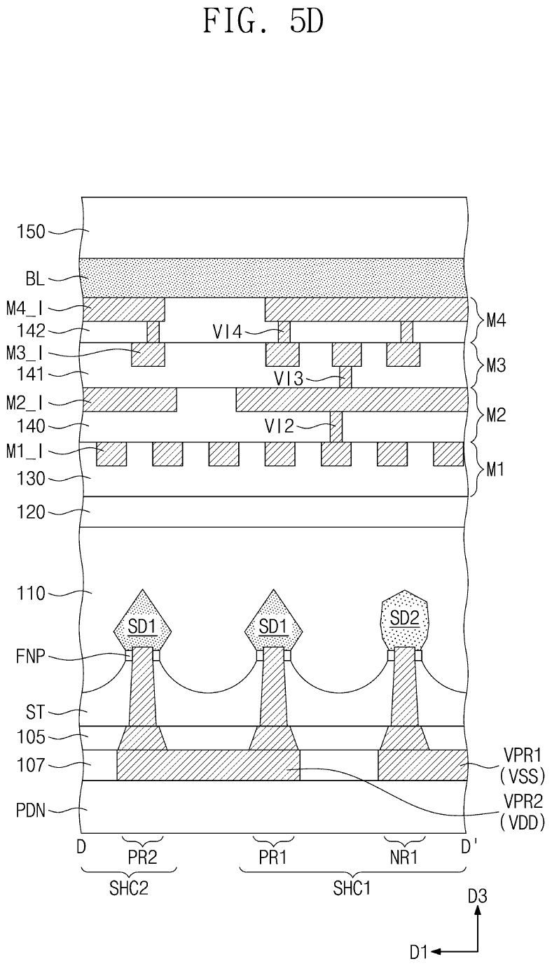

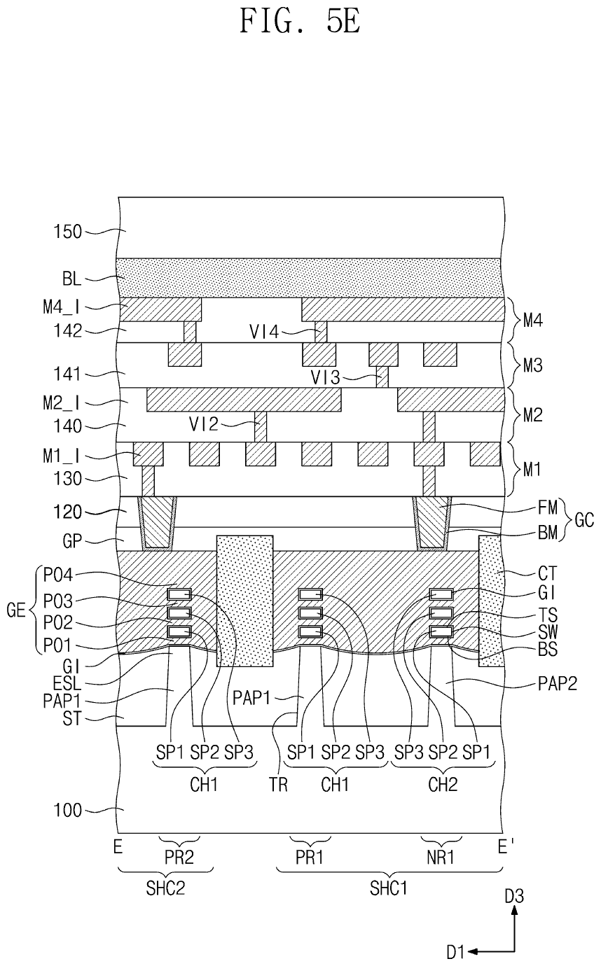

FIG. 4 is a plan view illustrating a semiconductor device according to an embodiment of the present disclosure. FIGS. 5A to 5F are sectional views taken along lines A-A′, B-B′, C-C′, D-D′, E-E′, and F-F′ of FIG. 4. FIGS. 4 and 5A to 5F illustrate an example of a detailed structure of the first and second single height cells SHC1 and SHC2 of FIG. 3.

Referring to FIGS. 4 and 5A to 5F, the first and second single height cells SHC1 and SHC2 may be provided on the main substrate 10. Logic transistors constituting a logic circuit may be disposed on each of the first and second single height cells SHC1 and SHC2.

A lower substrate 107 may be provided below the main substrate 10. The lower substrate 107 may include a silicon-based insulating layer. The lower substrate 107 may be an insulating substrate. For example, the lower substrate 107 may include a silicon oxide layer, a silicon nitride layer, or a silicon oxynitride layer. Lower power lines VPR1 to VPR3, which will be described below, may be disposed in the lower substrate 107.

The main substrate 10 may have the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first insulating pattern AP1 and a second insulating pattern AP2 may be defined by a trench TR, which is formed in an upper portion of the main substrate 10. The first insulating pattern AP1 may be provided on each of the first and second PMOSFET regions PR1 and PR2. The second insulating pattern AP2 may be provided on each of the first and second NMOSFET regions NR1 and NR2. The first and second insulating patterns AP1 and AP2 may be extended in the second direction D2. Each of the first and second insulating patterns AP1 and AP2 may be a vertically protruding portion of the main substrate 10.

A device isolation layer ST may at least partially fill the trench TR. The device isolation layer ST may cover a side surface of each of the first and second insulating patterns AP1 and AP2. The device isolation layer ST may include a silicon oxide layer. The device isolation layer ST may not cover or overlap first and second channel patterns CH1 and CH2, which will be described below.

A first channel pattern CH1 may be provided on the first insulating pattern AP1. A second channel pattern CH2 may be provided on the second insulating pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon. In an embodiment, each of the first to third semiconductor patterns SP1, SP2, and SP3 may be a nanosheet.

A plurality of first source/drain patterns SD1 may be provided on the first insulating pattern AP1. A plurality of first recesses RS1 may be formed in an upper portion of the first insulating pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second insulating pattern AP2. A plurality of second recesses RS2 may be formed in an upper portion of the second insulating pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between a pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. As an example, a top surface of each of the first and second source/drain patterns SD1 and SD2 may be positioned at substantially the same level as a top surface of the third semiconductor pattern SP3 relative to an upper surface of the lower substrate 107 in the third direction D3. However, in some embodiments, the top surface of each of the first and second source/drain patterns SD1 and SD2 may be at a higher level than the top surface of the third semiconductor pattern SP3 relative to an upper surface of the lower substrate 107 in the third direction D3.

The first source/drain patterns SD1 may include a semiconductor material (e.g., SiGe) whose lattice constant is greater than that of the first channel pattern CH1. In this case, the pair of the first source/drain patterns SD1 may exert a compressive stress on the first channel patterns CH1 therebetween. The second source/drain patterns SD2 may be formed of or include the same semiconductor material (e.g., Si) as the second channel pattern CH2.

Each of the first source/drain patterns SD1 may include a buffer layer BFL and a main layer MAL on the buffer layer BFL. Referring to FIG. 5A, the buffer layer BFL may cover or overlap an inner surface the first recess RS1. The main layer MAL may at least partially fill an unfilled region of the first recess RS1 that is covered with or overlapped by the buffer layer BFL. The main layer MAL may have a volume that is larger than that of the buffer layer BFL. Each of the buffer and main layers BFL and MAL may be formed of or include silicon germanium (SiGe). In detail, the buffer layer BFL may include a relatively low concentration of germanium (Ge). In another embodiment, the buffer layer BFL may include only silicon (Si), without germanium (Ge). A germanium concentration of the buffer layer BFL may range from 0 at % to 30 at %.

The main layer MAL may include a relatively high concentration of germanium. In an embodiment, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may include impurities (e.g., boron, gallium, or indium) that allows the first source/drain pattern SD1 to have a p-type conductivity. The impurity concentration of the main layer MAL may be higher than the impurity concentration of the buffer layer BFL.

The buffer layer BFL may protect the main layer MAL in a process of replacing second semiconductor layers SAL with first to third inner electrodes PO1, PO2, and PO3 of a gate electrode GE, as will be described below. In other words, the buffer layer BFL may prevent an etchant material, which is used to remove the second semiconductor layers SAL, from entering and etching the main layer MAL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity.

The gate electrodes GE may be provided to cross or extend into the first and second channel patterns CH1 and CH2 and to extend in the first direction D1. The gate electrodes GE may be arranged at a first pitch in the second direction D2. Each of the gate electrodes GE may be vertically overlapped by the first and second channel patterns CH1 and CH2.

The gate electrode GE may include a first inner electrode PO1 interposed between the insulating pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5E, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround at least a portion of the channel pattern.

In some embodiments, the first single height cell SHC1 may have a first border BD1 and a second border BD2, which are opposite to each other in the second direction D2. The first and second borders BD1 and BD2 may be extended in the first direction D1. The first single height cell SHC1 may have a third border BD3 and a fourth border BD4, which are opposite to each other in the first direction D1. The third and fourth borders BD3 and BD4 may be extended in the second direction D2.

Gate cutting patterns CT may be placed on a border of each of the first and second single height cells SHC1 and SHC2 parallel to the second direction D2. For example, the gate cutting patterns CT may be placed on the third and fourth borders BD3 and BD4 of the first single height cell SHC1. The gate cutting patterns CT may be arranged, at the first pitch, along the third border BD3. The gate cutting patterns CT may be arranged, at the first pitch, along the fourth border BD4. When viewed in a plan view, the gate cutting patterns CT on the third and fourth borders BD3 and BD4 may be overlapped by the gate electrodes GE, respectively. The gate cutting patterns CT may be formed of or include at least one of insulating materials (e.g., silicon oxide, silicon nitride, or combinations thereof).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. That is, the gate electrode GE extending in the first direction D1 may be divided into a plurality of the gate electrodes GE by the gate cutting patterns CT.

Referring to FIGS. 4 and 5A to 5F, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be at a higher level than a top surface of the gate electrode GE relative to the upper surface of the lower substrate 107 in the third direction D3. The top surfaces of the gate spacers GS may be coplanar with a top surface of a first interlayer insulating layer 110 relative to the upper surface of the lower substrate 107 in the third direction D3, which will be described below. The gate spacers GS may be formed of or include at least one of SiCN, SiCON, or SiN. In some embodiments, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover or overlap the top surface TS, the bottom surface BS, and the opposite side surfaces SW of each of the first to third semiconductor patterns SP1, SP2, and SP3. The gate insulating layer GI may cover or overlap the top surface of the device isolation layer ST below the gate electrode GE. The gate insulating layer GI may be interposed between the first inner electrode PO1 and the first and second insulating patterns AP1 and AP2.

In some embodiments, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which may adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). For example, the outer electrode PO4 of the gate electrode GE may include the first metal pattern and the second metal pattern on the first metal pattern.

Referring to FIG. 5B, inner spacers IP may be provided on the first and second NMOSFET regions NR1 and NR2. That is, the inner spacers IP may be provided on the second insulating pattern AP2. The inner spacers IP may be respectively interposed between the second source/drain pattern SD2 and the first to third inner electrodes PO1, PO2, and PO3 of the gate electrode GE. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

A first interlayer insulating layer 110 may be provided on the main substrate 10. The first interlayer insulating layer 110 may cover or overlap the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 may be formed on the first interlayer insulating layer 110 to cover or overlap the gate capping pattern GP.

A pair of division structures DB, which are opposite to each other in the second direction D2, may be provided at both sides of each of the first and second single height cells SHC1 and SHC2. For example, a pair of the division structures DB may be respectively provided on the first and second borders BD1 and BD2 of the first single height cell SHC1. The division structure DB may be extended in the first direction D1 to be parallel to the gate electrodes GE. A pitch between the division structure DB and the gate electrode GE adjacent thereto may be equal to the first pitch.

The division structure DB may be provided to penetrate or extend into the gate capping pattern GP and the gate electrode GE and may be extended into the first and second insulating patterns AP1 and AP2. The division structure DB may be provided to penetrate or extend into each of the first and second insulating patterns AP1 and AP2. The division structure DB may electrically separate an active region of each of the first and second single height cells SHC1 and SHC2 from an active region of a neighboring cell.

Active contacts AC may be provided to penetrate or extend into the first and second interlayer insulating layers 110 and 120 and to be electrically connected to the first and second source/drain patterns SD1 and SD2, respectively. The active contacts AC may electrically connect the first and second source/drain patterns SD1 and SD2 to metal layers that are described below. Each of the active contacts AC may be provided adjacent to a side of the gate electrode GE. When viewed in a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may cover or overlap at least a portion of the side surface of the gate spacer GS. Although not shown, the active contact AC may cover or overlap a portion of the top surface of the gate capping pattern GP.

A metal-semiconductor compound layer SC (e.g., a silicide layer) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate or extend into the second interlayer insulating layer 120 and the gate capping pattern GP and to be electrically connected to the gate electrodes GE, respectively. When viewed in a plan view, two gate contacts GC on the first single height cell SHC1 may be disposed to be overlapped by the first PMOSFET region PR1. In other words, two gate contacts GC on the first single height cell SHC1 may be provided on the first insulating pattern AP1 (e.g., see FIG. 5A). When viewed in a plan view, one gate contact GC on the first single height cell SHC1 may be disposed to be overlapped by the first NMOSFET region NR1. In other words, one gate contact GC on the first single height cell SHC1 may be provided on the second insulating pattern AP2 (e.g., see FIG. 5B).

The gate contact GC may be freely disposed on the gate electrode GE, without any restrictions on its position. For example, the gate contacts GC on the second single height cell SHC2 may be respectively disposed on the second PMOSFET region PR2, the second NMOSFET region NR2, and the device isolation layer ST at least partially filling the trench TR (e.g., see FIG. 4).

In an embodiment, referring to FIG. 5B, an upper portion of the active contact AC adjacent to the gate contact GC may be at least partially filled with an upper insulating pattern UIP. A bottom surface of the upper insulating pattern UIP may be lower than a bottom surface of the gate contact GC relative to the upper surface of the lower substrate 107 in the third direction D3. In other words, a top surface of the active contact AC adjacent to the gate contact GC may be formed at a level, which is lower than the bottom surface of the gate contact GC relative to the upper surface of the lower substrate 107 in the third direction D3, by the upper insulating pattern UIP. Accordingly, it may be possible to prevent or inhibit the gate contact GC and the active contact AC, which are adjacent to each other, from being in contact with each other and thereby prevent a short circuit issue from occurring therebetween. The upper insulating pattern UIP may be formed of or include at least one of silicon-based insulating materials (e.g., silicon oxide, silicon nitride, and silicon oxynitride).

Each of the active and gate contacts AC and GC may include a conductive pattern FM and a barrier pattern BM enclosing or at least partially surrounding the conductive pattern FM. For example, the conductive pattern FM may be formed of or include at least one of metallic materials (e.g., aluminum, copper, tungsten, molybdenum, and cobalt). The barrier pattern BM may be provided to cover or overlap side and bottom surfaces of the conductive pattern FM. In some embodiments, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CoN), or platinum nitride (PtN).

Referring to FIGS. 4 and 5C to 5F, first to third lower power lines VPR1, VPR2, and VPR3 may be provided in a lower portion of the main substrate 10. The first to third lower power lines VPR1, VPR2, and VPR3 may be extended in the second direction D2 to be parallel to each other. The first lower power line VPR1 may be disposed on the fourth border BD4 of the first single height cell SHC1. The second lower power line VPR2 may be disposed on the third border BD3 of the first single height cell SHC1. In other words, the first single height cell SHC1 may be defined between the first lower power line VPR1 and the second lower power line VPR2. The second single height cell SHC2 may be defined between the second lower power line VPR2 and the third lower power line VPR3.

In some embodiments, the first lower power line VPR1 may be vertically overlapped by the first NMOSFET region NR1. The second lower power line VPR2 may be vertically overlapped by the first PMOSFET region PRI and the second PMOSFET region PR2. The third lower power line VPR3 may be vertically overlapped by the second NMOSFET region NR2.

The first to third lower power lines VPR1 to VPR3 may be formed of or include at least one selected from the group consisting of copper, molybdenum, tungsten, and ruthenium. A bottom surface of each of the first to third lower power lines VPR1 to VPR3 may be coplanar with a bottom surface of the main substrate 10.

A power delivery network layer PDN may be provided on the bottom surface of the main substrate 10. The power delivery network layer PDN may include a plurality of lower interconnection lines, which are electrically connected to the first to third lower power lines VPR1 to VPR3. As an example, the power delivery network layer PDN may include a wiring network, which may apply the source voltage VSS to the first and third lower power lines VPR1 and VPR3. The power delivery network layer PDN may include a wiring network, which may apply the drain voltage VDD to the second lower power line VPR2.

The main substrate 10 may include a first substrate 105 and a second substrate 100. The first substrate 105 may include a material different from the second substrate 100. For example, the first substrate 105 may be an insulating substrate. The first substrate 105 may include a silicon-based insulating layer. For example, the first substrate 105 may include silicon oxide layer, a silicon nitride layer, or a silicon oxynitride layer. The second substrate 100 may be a silicon substrate. The first and second substrates 105 and 100 may include materials whose etch rates are different from each other.

Referring to FIGS. 4, 5A, 5B, and 5D, a backside contact BAC may be provided to penetrate or extend into the first substrate 105 and to vertically extend from the second lower power line VPR2 to the first source/drain pattern SD1. The backside contact BAC may be provided to penetrate or extend into the first substrate 105 and to vertically extend from the first lower power line VPR1 to the second source/drain pattern SD2.

The backside contact BAC may be a conductive pillar-shaped pattern vertically and electrically connecting the second lower power line VPR2 to the first source/drain pattern SD1. The drain voltage VDD may be applied to the first source/drain pattern SD1 through the backside contact BAC.

The backside contact BAC may be a conductive pillar-shaped pattern vertically and electrically connecting the first lower power line VPR1 to the second source/drain pattern SD2. The source voltage VSS may be applied to the second source/drain pattern SD2 through the backside contact BAC.

A backside via BVI may be provided to penetrate or extend into the lower substrate 107 and to vertically extend from the backside contact BAC to the first and second lower power lines VPR1 and VPR2. The backside via BVI may be provided to connect the backside contact BAC to the first and second lower power lines VPR1 and VPR2 vertically and electrically.

Referring back to FIGS. 4 and 5A to 5F, a third interlayer insulating layer 130, a fourth interlayer insulating layer 140, a fifth interlayer insulating layer 141, and a sixth interlayer insulating layer 142 may be sequentially provided on the second interlayer insulating layer 120. In some embodiments, each of the first to sixth interlayer insulating layers 110, 120, 130, 140, 141, and 142 may include a silicon oxide layer. As another example, at least one of the third to sixth interlayer insulating layers 130, 140, 141, and 142 may be omitted. As an additional example, at least one interlayer insulating layer may be formed on the sixth interlayer insulating layer 142.

A first metal layer M1 may be provided in the third interlayer insulating layer 130. The first metal layer M1 may include first interconnection lines M1_I. The first interconnection lines M1_I of the first metal layer M1 may be extended in the second direction D2 to be parallel to each other.

According to an embodiment of the present disclosure, a power line, which is used to supply a power to the single height cell SHC, may be provided in the form of the lower power line VPR1, VPR2, or VPR3 and may be buried in the lower substrate 107. Thus, the power line may be omitted from the first metal layer M1. The first interconnection lines M1_I, which are used for signal transmission, may be disposed in the first metal layer M1.

The first metal layer M1 may further include first vias VI1. The first vias VI1 may be respectively provided below the first interconnection lines M1_I of the first metal layer M1. The first interconnection line M1_I of the first metal layer M1 may be electrically connected to the active contact AC through the first via VI1. The first interconnection line M1_I of the first metal layer M1 may be electrically connected to the gate contact GC through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present embodiments may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line-shaped or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The first interconnection line M1_I of the first metal layer M1 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. For example, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt).

A third metal layer M3 may be provided in the fifth interlayer insulating layer 141. The third metal layer M3 may include third interconnection lines M3_1. The third metal layer M3 may further include third vias VI3. The third vias VI3 may be provided below the third interconnection lines M3_1 of the third metal layer M3, respectively. A second interconnection line M2_1 of the second metal layer M2 and the third interconnection line M3_1 of the third metal layer M3 may be electrically connected to each other through the third via VI3.

A fourth metal layer M4 may be provided in the sixth interlayer insulating layer 142. The fourth metal layer M4 may include fourth interconnection lines M4_1. The fourth metal layer M4 may further include fourth vias VI4. The fourth vias VI4 may be provided below the fourth interconnection lines M4_1 of the fourth metal layer M4, respectively. The third interconnection line M3_1 of the third metal layer M3 and the fourth interconnection line M4_1 of the fourth metal layer M4 may be electrically connected to each other through the fourth via VI4.

Although not shown, a plurality of metal layers (e.g., M5, M6, and so forth) may be additionally stacked on the sixth interlayer insulating layer 142. Each of the stacked metal layers may include interconnection lines, which are used as a routing structure between cells.

Referring to FIGS. 5A, 5B, and 5F, the backside contact BAC may be provided in the first substrate 105, and a protection structure PS, which will be described below, may be provided on the second substrate 100.

The protection structure PS may be provided on the second substrate 100. The protection structure PS may include the first source/drain pattern SD1 and a first doping pattern DP1. The first doping pattern DP1 may be provided in the second substrate 100. The first doping pattern DP1 may be provided below the first source/drain pattern SD1. The first doping pattern DP1 may be connected to a lower portion of the first source/drain pattern SD1. For example, the first doping pattern DP1 may be in contact with the main layer MAL of the first source/drain pattern SD1.

The first doping pattern DP1 may include impurities. The first doping pattern DP1 may include dopants different from the first source/drain pattern SD1. One of the first source/drain pattern SD1 and the first doping pattern DP1 may include p-type impurities, and the other may include n-type impurities. For example, the first source/drain pattern SD1 may include the p-type impurities (e.g., boron, gallium, or indium), and the first doping pattern DP1 may include the n-type impurities (e.g., phosphorus, arsenic, or antimony).

The first doping pattern DP1 and the first source/drain pattern SD1 may include impurities of different conductivity types. Accordingly, the first doping pattern DP1 and the first source/drain pattern SD1 may be used as a conduction path for a forward current.

The protection structure PS may include the second source/drain pattern SD2 and a second doping pattern DP2. The second doping pattern DP2 may be provided in the second substrate 100. The second doping pattern DP2 may be provided below the second source/drain pattern SD2. The second doping pattern DP2 may be connected to a lower portion of the second source/drain pattern SD2.

The second doping pattern DP2 may include impurities. The second doping pattern DP2 may include dopants different from the second source/drain pattern SD2. One of the second source/drain pattern SD2 and the second doping pattern DP2 may include p-type impurities, and the other may contain n-type impurities. For example, the second source/drain pattern SD2 may include the n-type impurities (e.g., phosphorus, arsenic, or antimony), and the second doping pattern DP2 may include the p-type impurities (e.g., boron, gallium, or indium).

The second doping pattern DP2 and the second source/drain pattern SD2 may be doped with impurities and may have different conductivity types from each other. Accordingly, the second doping pattern DP2 and the second source/drain pattern SD2 may be used as a conduction path for a forward current.

The first doping pattern DP1 may have a conductivity type different from the second doping pattern DP2. One of the first and second doping patterns DP1 and DP2 may include p-type impurities, and the other may contain n-type impurities. For example, the first doping pattern DP1 may include the n-type impurities (e.g., phosphorus, arsenic, or antimony), and the second doping pattern DP2 may contain the p-type impurities (e.g., boron, gallium, or indium).

The first doping pattern DP1 may include impurities of the same conductivity type as the second source/drain pattern SD2. The second doping pattern DP2 may include impurities of the same conductivity type as the first source/drain pattern SD1. For example, the first doping pattern DP1 and the second source/drain pattern SD2 may include the n-type impurities, and the second doping pattern DP2 and the first source/drain pattern SD1 may include the p-type impurities. As another example, the first doping pattern DP1 and the second source/drain pattern SD2 may include the p-type impurities, and the second doping pattern DP2 and the first source/drain pattern SD1 may include the n-type impurities.

The backside via BVI may be in contact with the first and second doping patterns DP1 and DP2. The backside via BVI may be provided below the first and second doping patterns DP1 and DP2. The backside via BVI may vertically and electrically connect the first doping pattern DP1 to the second lower power line VPR2. The backside via BVI may vertically and electrically connect the second doping pattern DP2 to the first lower power line VPR1.

In some embodiments, the fourth interconnection lines M4_1 of the fourth metal layer M4 may be the uppermost ones of the interconnection layers. A bonding layer BL may be provided on the sixth interlayer insulating layer 142. A sustain substrate 150 may be provided on the bonding layer BL. The bonding layer BL may include an insulating material. The sustain substrate 150 may be a semiconductor substrate that is formed of or includes silicon, germanium, silicon germanium, a compound semiconductor material, or the like. As an example, the sustain substrate 150 may be a silicon substrate.

An impurity region 160 may be provided in the sustain substrate 150. The impurity region 160 may include n-type and/or p-type impurities. For example, the impurity region 160 may include p-type impurities (e.g., boron, gallium, or indium). The impurity region 160 may include n-type impurities (e.g., phosphorus, arsenic, or antimony). In some embodiments, the impurity region 160 in the sustain substrate 150 may be omitted.

A bonding contact BC may be provided in the bonding layer BL. The bonding contact BC may vertically penetrate or extend into the bonding layer BL. The bonding contact BC may be provided below the impurity region 160 and may be connected to a bottom portion of the impurity region 160. The fourth interconnection lines M4_1 of the fourth metal layer M4 and the impurity region 160 of the sustain substrate 150 may be electrically connected to each other through the bonding contact BC.

In some embodiments, a pad PD may be provided between the bonding contact BC and the impurity region 160. As an example, the pad PD may be a metal pad that is interposed between the bonding contact BC and the impurity region 160. The metal pad may be provided below a bottom surface of the impurity region 160. Due to the metal pad, the bonding contact BC and the impurity region 160 may be robustly coupled to each other.

As another example, the pad PD may be a silicide pad that is interposed between the bonding contact BC and the impurity region 160. The silicide pad may be provided on a top surface of the bonding contact BC. Due to the silicide pad, the bonding contact BC and the impurity region 160 may be robustly coupled to each other. For example, the silicide pad may be formed of or include at least one of titanium silicide, tantalum silicide, tungsten silicide, nickel silicide, or cobalt silicide.

As another example, the protection structure PS may be formed in a dummy region. The dummy region may not include a logic device, unlike the logic cell. For example, the dummy region may not be used to execute a circuit function.

As another example, the division structure DB may be provided between the first substrate 105 and the second substrate 100. The division structures DB may be respectively provided at both sides of the second substrate 100. The first substrate 105 may be separated from the second substrate 100 by the division structure DB.

According to some embodiments of the present disclosure, the semiconductor device may include the protection structure PS, which includes source/drain patterns SD and a doping pattern DP. The protection structure PS may serve as a diode. The doping pattern DP may be electrically connected to the first and second lower power lines VPR1 and VPR2. The source/drain patterns SD may be electrically connected to the impurity region 160 of the sustain substrate 150 through the active contact AC, the stacked metal layers M1, M2, M3, and M4, and the bonding contact BC. Accordingly, electric charges and heat, which are generated in a backside process, may be exhausted or dissipated to the sustain substrate 150 through the protection structure PS. As a result, the electrical and reliability characteristics of the semiconductor device may be improved.

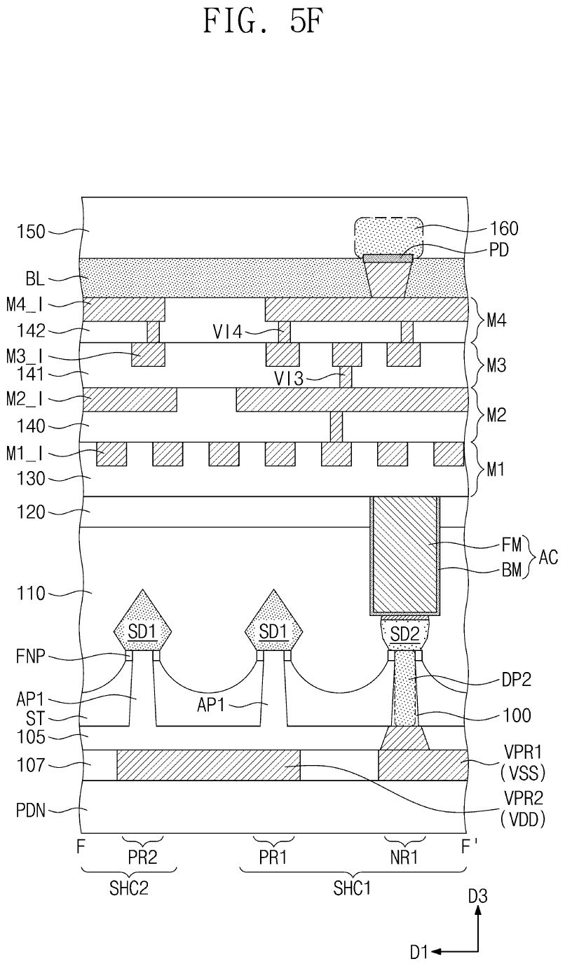

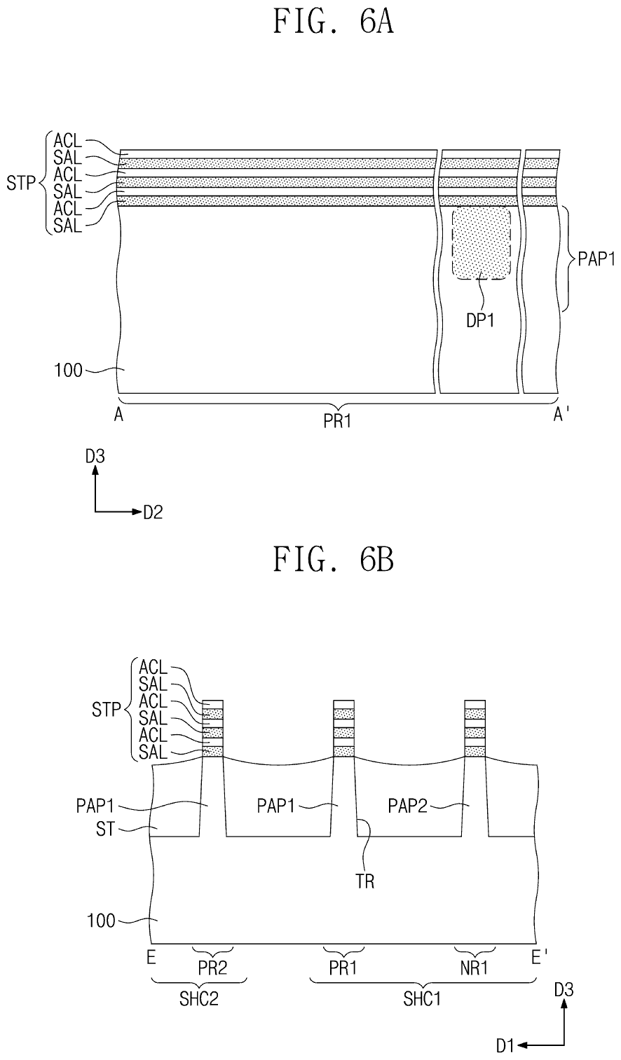

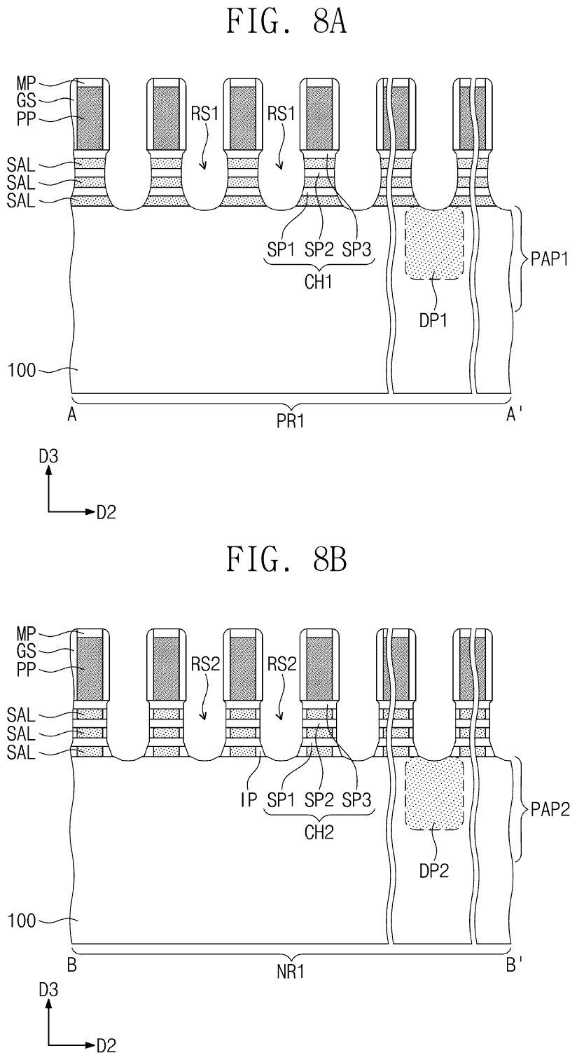

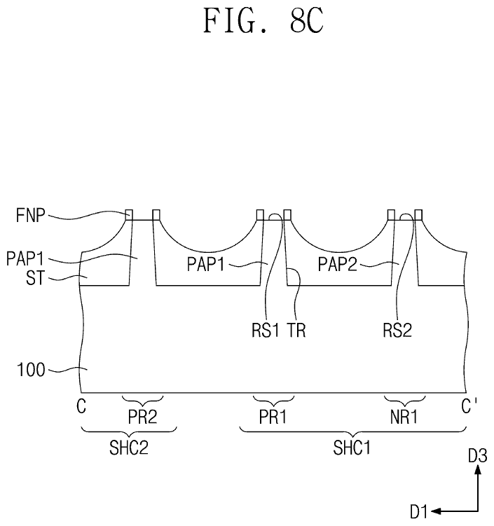

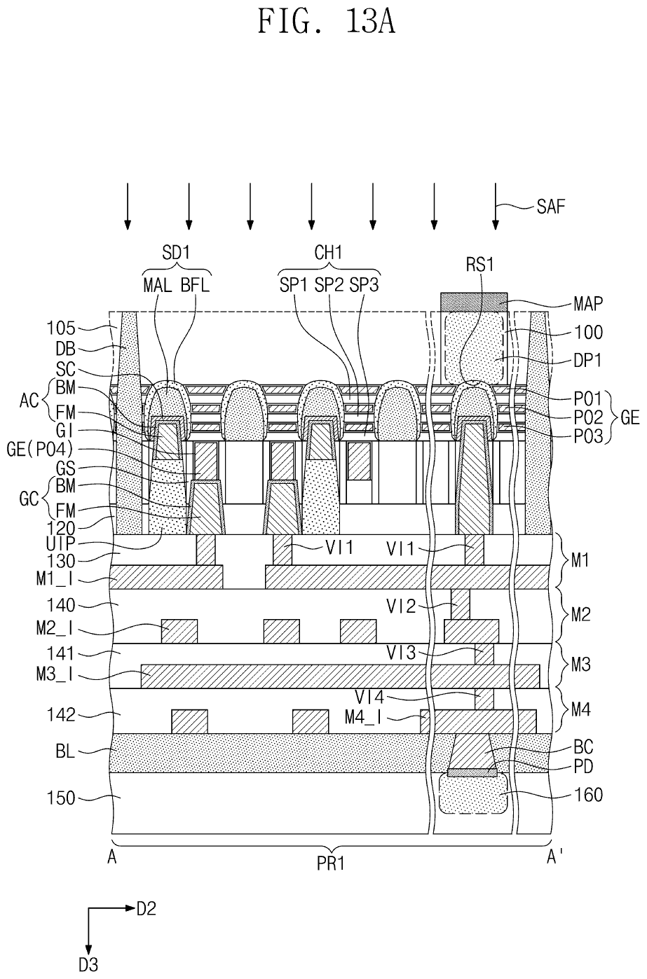

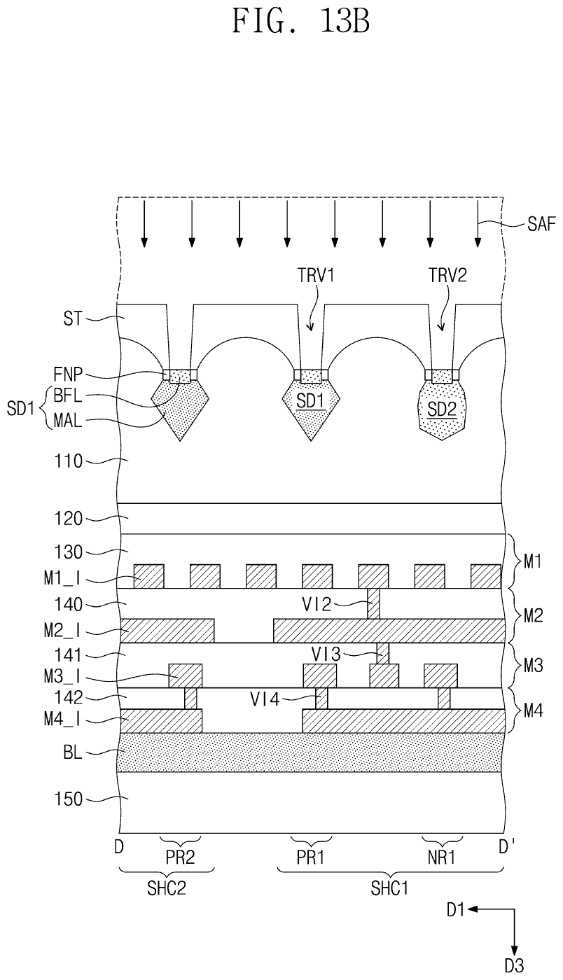

FIGS. 6A to 15B are sectional views illustrating a method of fabricating a semiconductor device according to an embodiment of the present disclosure. In detail, FIGS. 6A, 7A, 8A, 9A, 10A, 11A, 12A, 13A, 14A, and 15A are sectional views taken along the line A-A′ of FIG. 4. FIGS. 8B, 9B, 10B, 11B, and 12B are sectional views taken along the line B-B′ of FIG. 4. FIGS. 8C, 9C, and 12C are sectional views taken along the line C-C′ of FIG. 4. FIGS. 13B, 14B, and 15B are sectional views taken along the line D-D′ of FIG. 4. FIGS. 6B, 7B, 10C, and 12D are sectional views taken along the line E-E′ of FIG. 4.

Referring to FIGS. 6A and 6B, a semiconductor substrate 100 including the first and second PMOSFET regions PR1 and PR2 and the first and second NMOSFET regions NR1 and NR2 may be provided. The second substrate 100 described above may be a portion of the semiconductor substrate 100. In some embodiments, the semiconductor substrate 100 may be a silicon wafer.

The first and second doping patterns DP1 and DP2 may be formed in an upper portion of the semiconductor substrate 100. In detail, the formation of the first and second doping patterns DP1 and DP2 may include injecting impurities into the semiconductor substrate 100 in an in-situ manner. For example, the first doping pattern DP1 may include p-type impurities (e.g., boron, gallium, or indium). The second doping pattern DP2 may include n-type impurities (e.g., phosphorus, arsenic, or antimony). As another example, only one of the first and second doping patterns DP1 and DP2 may be formed.

First semiconductor layers ACL and second semiconductor layers SAL may be alternately stacked on the semiconductor substrate 100. Each of the first and second semiconductor layers ACL and SAL may be formed of or include at least one of silicon (Si), germanium (Ge), or silicon-germanium (SiGe), but the first and second semiconductor layers ACL and SAL may be formed of different materials from each other.

The second semiconductor layer SAL may be formed of or include a material that is chosen to have an etch selectivity with respect to the first semiconductor layer ACL. For example, the first semiconductor layers ACL may be formed of or include silicon (Si), and the second semiconductor layers SAL may be formed of or include silicon-germanium (SiGe). A germanium concentration of each of the second semiconductor layers SAL may range from 10 at % to 30 at %.

Mask patterns may be formed on the first and second PMOSFET regions PR1 and PR2 and the first and second NMOSFET regions NR1 and NR2 of the semiconductor substrate 100, respectively. The mask pattern may be a line-shaped or bar-shaped pattern that is extended in the second direction D2.

A patterning process using the mask patterns as an etch mask may be performed to form the trench TR defining a first active pattern PAP1 and a second active pattern PAP2. The first active pattern PAP1 may be formed on each of the first and second PMOSFET regions PR1 and PR2. The second active pattern PAP2 may be formed on each of the first and second NMOSFET regions NR1 and NR2. When viewed in a plan view, the first and second active patterns PAP1 and PAP2 may be line-shaped patterns, which are extended in the second direction D2 to be parallel to each other.

A stacking pattern STP may be formed on each of the first and second active patterns PAP1 and PAP2. The stacking pattern STP may further include the first semiconductor layers ACL and the second semiconductor layers SAL, which are alternately stacked. The stacking pattern STP may be formed along with the first and second active patterns PAP1 and PAP2, during the patterning process. The first active pattern PAP1 may include the first doping pattern DP1, which is formed in an upper portion thereof. The second active pattern PAP2 may include the second doping pattern DP2, which is formed in an upper portion thereof.

The device isolation layer ST may be formed to at least partially fill the trench TR. In detail, an insulating layer may be formed on the semiconductor substrate 100 to cover or overlap the first and second active patterns PAP1 and PAP2 and the stacking patterns STP. The device isolation layer ST may be formed by recessing the insulating layer to expose the stacking patterns STP.

The device isolation layer ST may be formed of or include at least one insulating material (e.g., silicon oxide). The stacking patterns STP may be placed at a level higher than the device isolation layer ST relative to the upper surface of the semiconductor substrate 100 in the third direction D3 and may be exposed to the outside of the device isolation layer ST. In other words, the stacking patterns STP may protrude or extend in an upward direction, relative to device isolation layer ST.

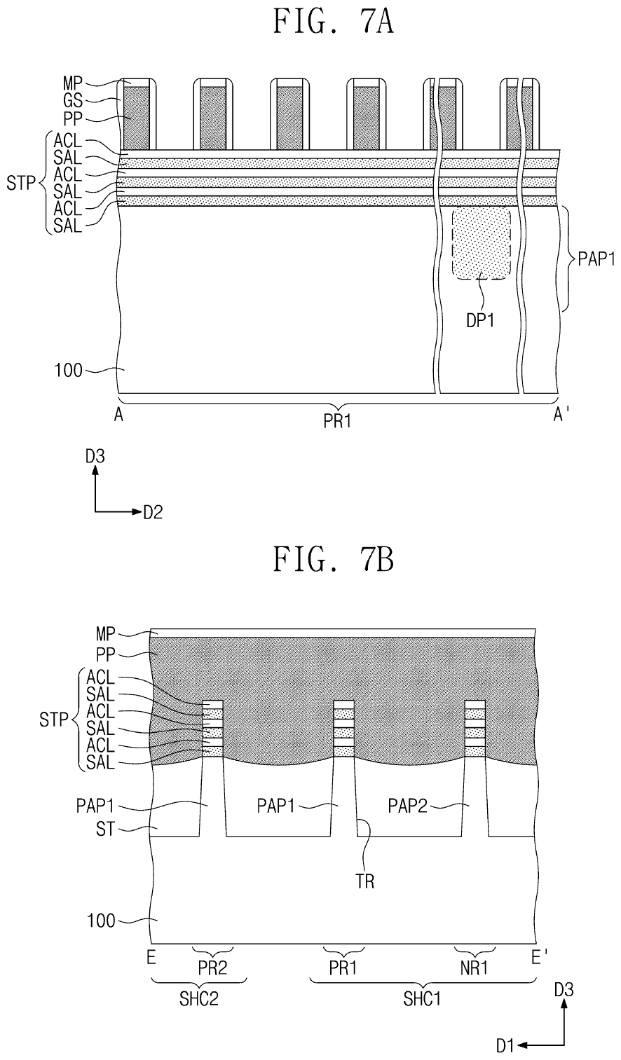

Referring to FIGS. 7A and 7B, sacrificial patterns PP may be formed on the semiconductor substrate 100 to cross the stacking patterns STP. Each of the sacrificial patterns PP may be a line-shaped or bar-shaped pattern that is extended in the first direction D1. The sacrificial patterns PP may be arranged at a first pitch in the second direction D2.

In detail, the formation of the sacrificial patterns PP may include forming a sacrificial layer on the semiconductor substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the semiconductor substrate 100 and anisotropically etching the gate spacer layer. The gate spacer layer may be formed of or include at least one of SiCN, SiCON, or SiN. In some embodiments, the gate spacer layer may be a multi-layered structure including at least two of SiCN, SiCON, or SiN.

Referring to FIGS. 8A to 8C, first recesses RS1 may be formed in the stacking pattern STP on the first active pattern PAP1. Second recesses RS2 may be formed in the stacking pattern STP on the second active pattern PAP2. During the formation of the first and second recesses RS1 and RS2, the device isolation layer ST may also be recessed at both sides of each of the first and second active patterns PAP1 and PAP2 (e.g., see FIG. 8C).

In detail, the first recesses RS1 may be formed by etching the stacking pattern STP on the first active pattern PAP1 using the hard mask patterns MP and the gate spacers GS as an etch mask. The first recess RS1 may be formed between a pair of the sacrificial patterns PP. The second recesses RS2 in the stacking pattern STP on the second active pattern PAP2 may be formed by the same method as that for the first recesses RS1.

Referring back to FIG. 8C, a fence pattern FNP may be formed on each of the first and second active patterns PAP1 and PAP2. The fence pattern FNP may be a remaining portion of the gate spacer GS.

Referring back to FIGS. 8A to 8C, the first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between adjacent ones of the second recesses RS2 may constitute the second channel pattern CH2.

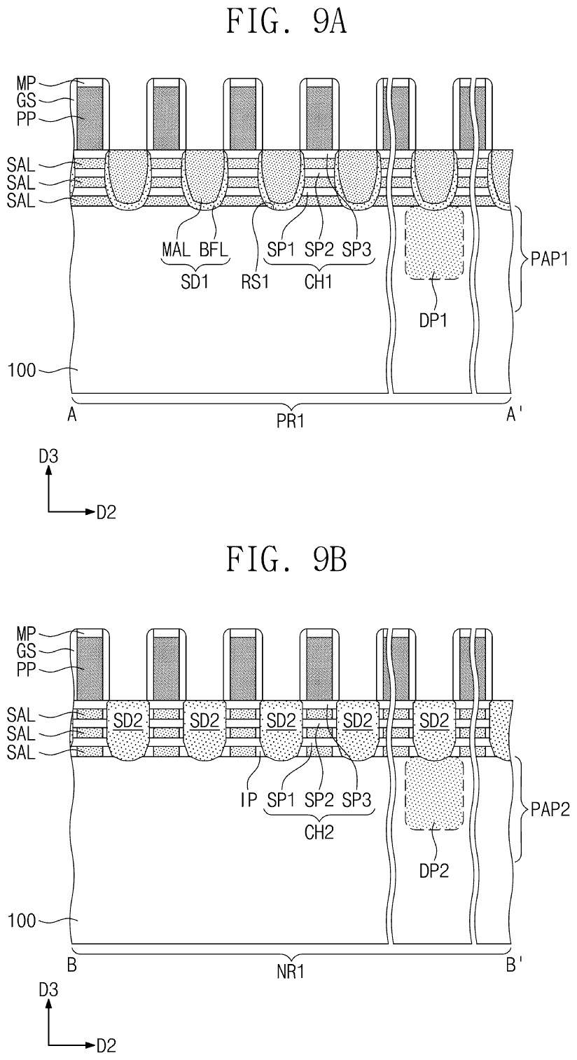

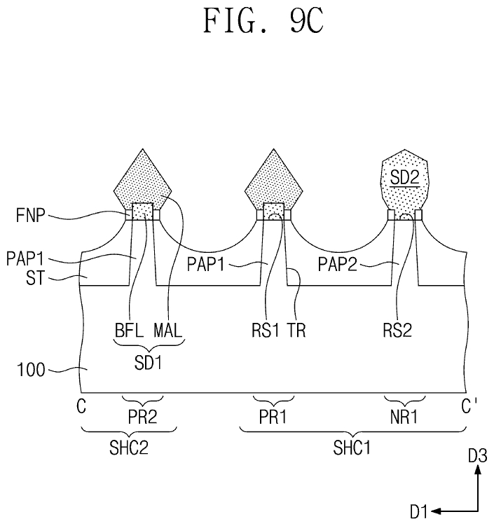

Referring to FIGS. 9A to 9C, the first source/drain patterns SD1 may be formed in the first recesses RS1, respectively. In detail, the buffer layer BFL may be formed by a first SEG process using an inner surface of the first recess RS1 as a seed layer. The buffer layer BFL may be grown using the first to third semiconductor patterns SP1, SP2, and SP3 and the semiconductor substrate 100, which are exposed through the first recess RS1, as a seed layer. As an example, the first SEG process may include a chemical vapor deposition (CVD) process or a molecular beam epitaxy (MBE) process.

The buffer layer BFL may be formed of or include a semiconductor material (e.g., SiGe) whose lattice constant is larger than that of the semiconductor substrate 100. The buffer layer BFL may include a relatively low concentration of germanium (Ge). In another embodiment, the buffer layer BFL may include only silicon (Si), without germanium (Ge). A germanium concentration of the buffer layer BFL may range from 0 at % to 30 at %.

A second SEG process may be performed on the buffer layer BFL to form the main layer MAL. The main layer MAL may be formed to at least partially fill the first recess RS1. The main layer MAL may include a relatively high concentration of germanium. In an embodiment, the germanium concentration of the main layer MAL may range from 30 at % to 70 at %.

In some embodiments, a third SEG process may be performed on the main layer MAL to form a capping layer. The capping layer may be formed of or include silicon (Si). A silicon concentration of the capping layer may range from 98 at % to 100 at %.

The first source/drain pattern SD1 may be doped in-situ with p-type impurities (e.g., boron, gallium, or indium) during the formation of the buffer and main layers BFL and MAL. Alternatively, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a selective epitaxial growth (SEG) process, in which an inner surface of the second recess RS2 is used as a seed layer. In an embodiment, the second source/drain pattern SD2 may be formed of or include the same semiconductor material (e.g., Si) as the semiconductor substrate 100.

During the formation of the second source/drain pattern SD2, the second source/drain pattern SD2 may be doped in-situ with n-type impurities (e.g., phosphorus, arsenic, or antimony). Alternatively, impurities may be injected into the second source/drain pattern SD2, after the formation of the second source/drain pattern SD2.

In some embodiments, before the formation of the second source/drain pattern SD2, the inner spacer IP may be formed by replacing a portion of the second semiconductor layer SAL, which is exposed through the second recess RS2, with an insulating material. As a result, the inner spacers IP may be respectively formed between the second source/drain pattern SD2 and the second semiconductor layers SAL.

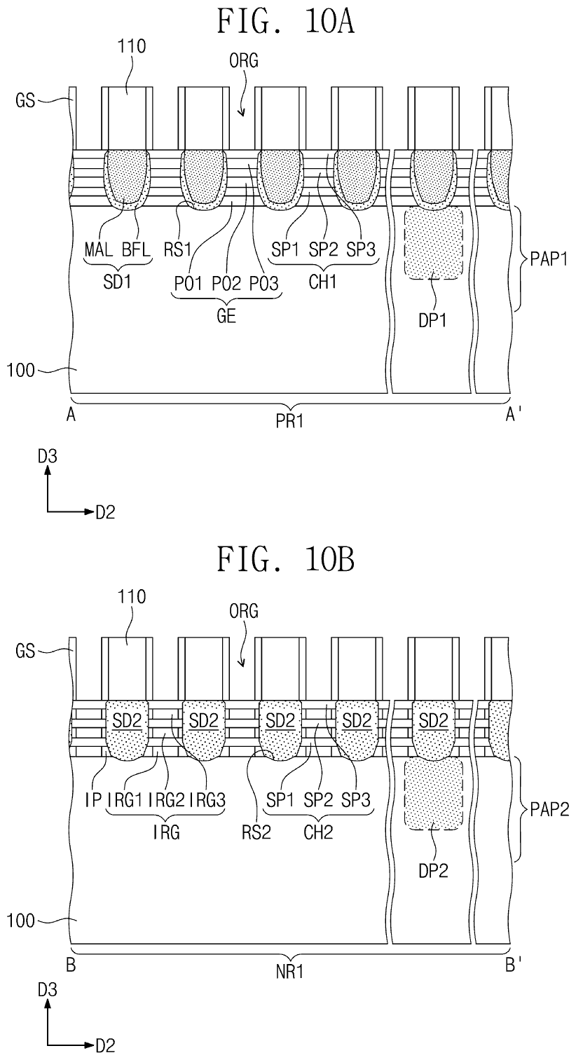

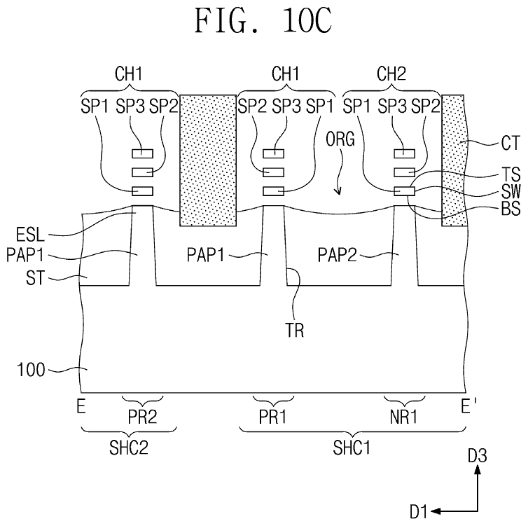

Referring to FIGS. 10A to 10C, the first interlayer insulating layer 110 may be formed to cover or overlap the first and second source/drain patterns SD1 and SD2, the hard mask patterns MP, and the gate spacers GS. In some embodiments, the first interlayer insulating layer 110 may include a silicon oxide layer.

The first interlayer insulating layer 110 may be planarized to expose the top surfaces of the sacrificial patterns PP. The planarization of the first interlayered insulating layer 110 may be performed using an etch-back or chemical mechanical polishing (CMP) process. All the hard mask patterns MP may be removed during the planarization process. As a result, the first interlayer insulating layer 110 may be formed to have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP on the third and fourth borders BD3 and BD4 of the first single height cell SHC1 may be selectively opened. The opened region of the sacrificial pattern PP may be selectively etched and removed. The gate cutting pattern CT may be formed by at least partially filling a space, which is formed by removing the sacrificial pattern PP, with an insulating material (e.g., see FIG. 10C).

The exposed sacrificial patterns PP may be selectively removed. As a result of the removal of the sacrificial patterns PP, an outer region ORG exposing the first and second channel patterns CH1 and CH2 may be formed (e.g., see FIG. 10C). The removal of the sacrificial patterns PP may include a wet etching process which is performed using an etching solution capable of selectively etching polysilicon.

The second semiconductor layers SAL, which are exposed through the outer region ORG, may be selectively removed to form inner regions IRG (e.g., see FIG. 10C). In detail, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which has a relatively high germanium concentration, at a high etch rate. For example, the etching process may be chosen to have a high etch rate to a silicon germanium layer whose germanium concentration is higher than 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

Referring back to FIG. 10C, as a result of the selective removal of the second semiconductor layers SAL, the stacked first to third semiconductor patterns SP1, SP2, and SP3 may be left on each of the first and second active patterns PAP1 and PAP2. Empty regions, which are formed by removing the second semiconductor layers SAL, may be used as first to third inner regions IRG1, IRG2, and IRG3, respectively. In detail, the first inner region IRG1 may be formed between the first and second active patterns PAP1 and PAP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

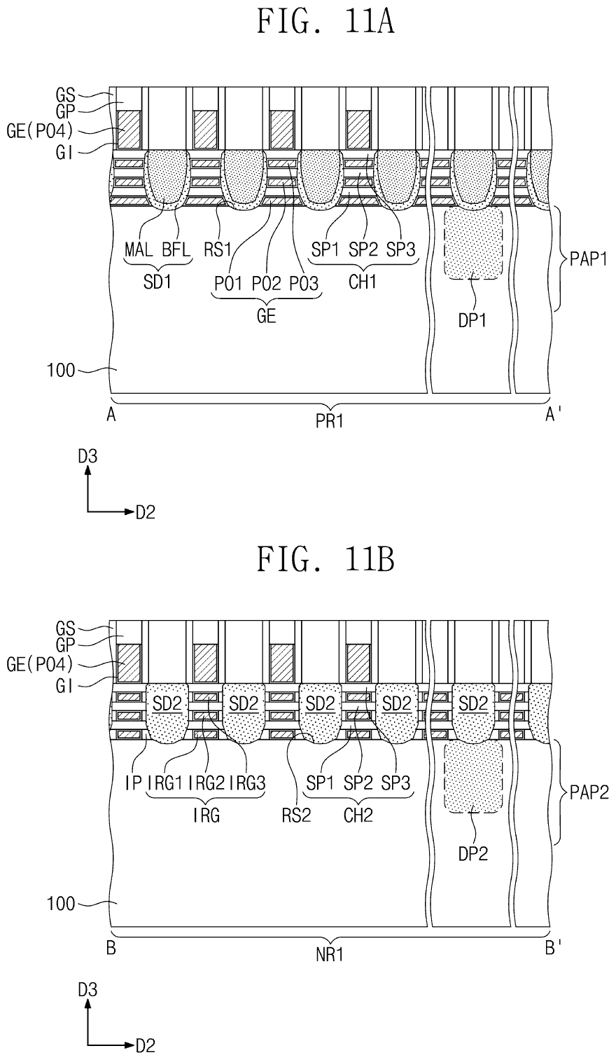

Referring to FIGS. 11A and 11B, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3, which are respectively formed in the first to third inner regions IRG1, IRG2, and IRG3, and the outer electrode PO4, which is formed in the outer region ORG.

The gate electrode GE may be vertically recessed to have a reduced height. Upper portions of the gate cutting patterns CT may be slightly recessed, during the recessing of the gate electrode GE. The gate capping pattern GP may be formed on the recessed gate electrode GE.

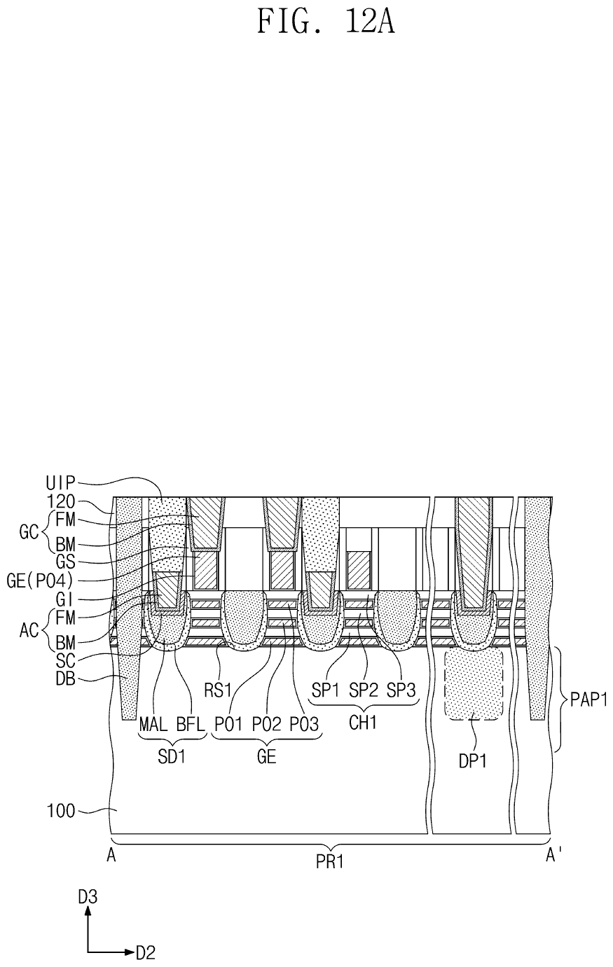

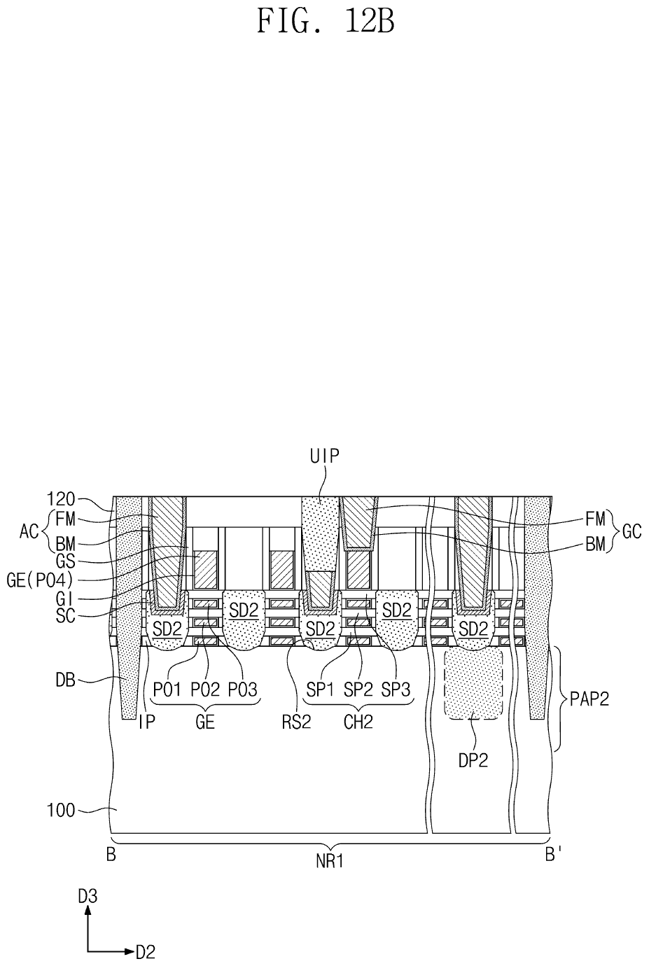

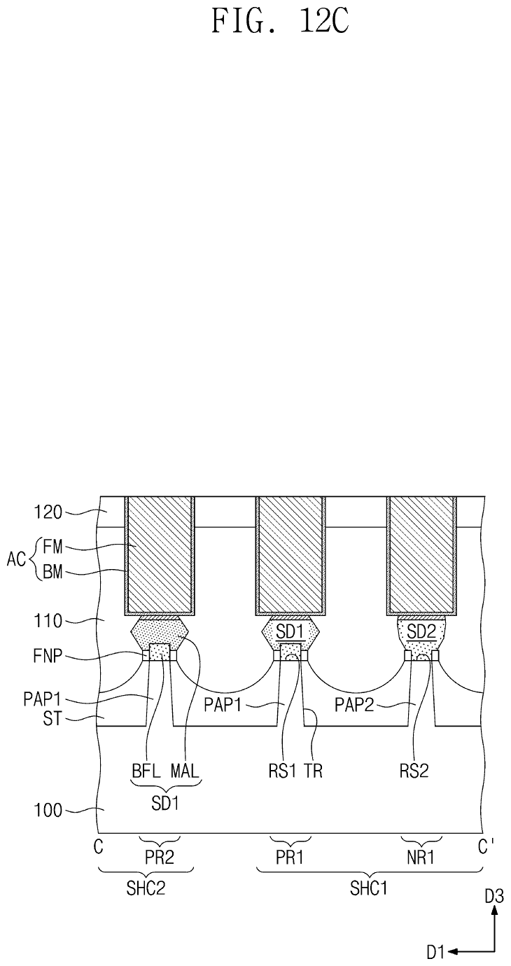

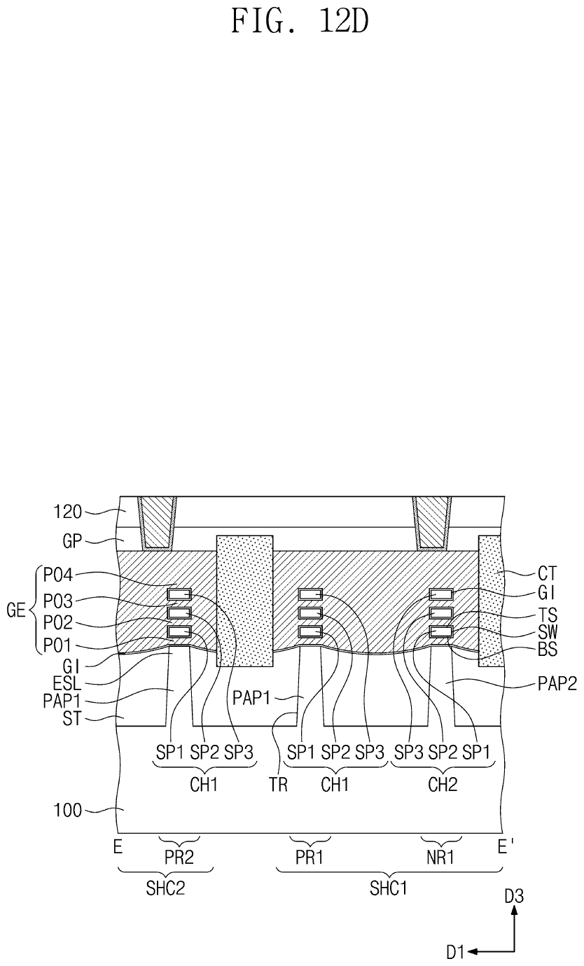

Referring to FIGS. 12A to 12D, the second interlayer insulating layer 120 may be formed on the first interlayer insulating layer 110. The second interlayer insulating layer 120 may include a silicon oxide layer. The active contact AC may be formed to penetrate or extend into the second interlayer insulating layer 120 and the first interlayer insulating layer 110 and to be electrically connected to at least one of the first and second source/drain patterns SD1 and SD2. The gate contact GC may be formed to penetrate or extend into the second interlayer insulating layer 120 and the gate capping pattern GP and may be electrically connected to the gate electrode GE.

The formation of the active and gate contacts AC and GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

Referring back to FIGS. 4 and 5A to 5F, the third interlayer insulating layer 130 may be formed on the active contacts AC and the gate contacts GC. The first metal layer M1 may be formed in the third interlayer insulating layer 130. The first metal layer M1 may include the first interconnection line M1_I, which is electrically connected to at least one of the active and gate contacts AC and GC.

The fourth interlayer insulating layer 140 may be formed on the third interlayer insulating layer 130. The second metal layer M2 may be formed in the fourth interlayer insulating layer 140. The fifth interlayer insulating layer 141 may be formed on the fourth interlayer insulating layer 140. The third metal layer M3 may be formed in the fifth interlayer insulating layer 141. The sixth interlayer insulating layer 142 may be formed on the fifth interlayer insulating layer 141. The fourth metal layer M4 may be formed in the sixth interlayer insulating layer 142.

Referring to FIGS. 13A and 13B, when a back end of line (BEOL) process is finished, the semiconductor substrate 100 may be inverted such that a bottom surface of the semiconductor substrate 100 is exposed to the outside. A mask pattern MAP may be formed on only the first and second doping patterns DP1 and DP2. The mask pattern MAP may be formed of or include a material having an etch selectivity with respect to the semiconductor substrate 100.

An etching process using the mask pattern MAP as a mask may be performed to remove a portion of the exposed semiconductor substrate 100. A portion of the exposed semiconductor substrate 100, which is adjacent to the first and second doping patterns DP1 and DP2, may not be removed and may be left as the second substrate 100.

In some embodiments, the removal of the semiconductor substrate 100 may include performing a planarization process SAF on the bottom surface of the semiconductor substrate 100 to reduce a thickness of the semiconductor substrate 100, forming the mask pattern MAP on the bottom surface of the semiconductor substrate 100, and performing a cleaning process using the mask pattern MAP as a mask to selectively remove silicon (Si) from the semiconductor substrate 100.

As another example, the division structures DB may be provided at both sides of the second substrate 100, respectively. The mask pattern MAP may be provided between the division structures DB, which are provided at both sides of the second substrate 100.

As a result of the removal of the semiconductor substrate 100, a first backside trench TRV1 may be formed in a region occupied by the first active pattern PAP1. As a result of the removal of the semiconductor substrate 100, a second backside trench TRV2 may be formed in a region occupied by the second active pattern PAP2 (e.g., see FIG. 13B).

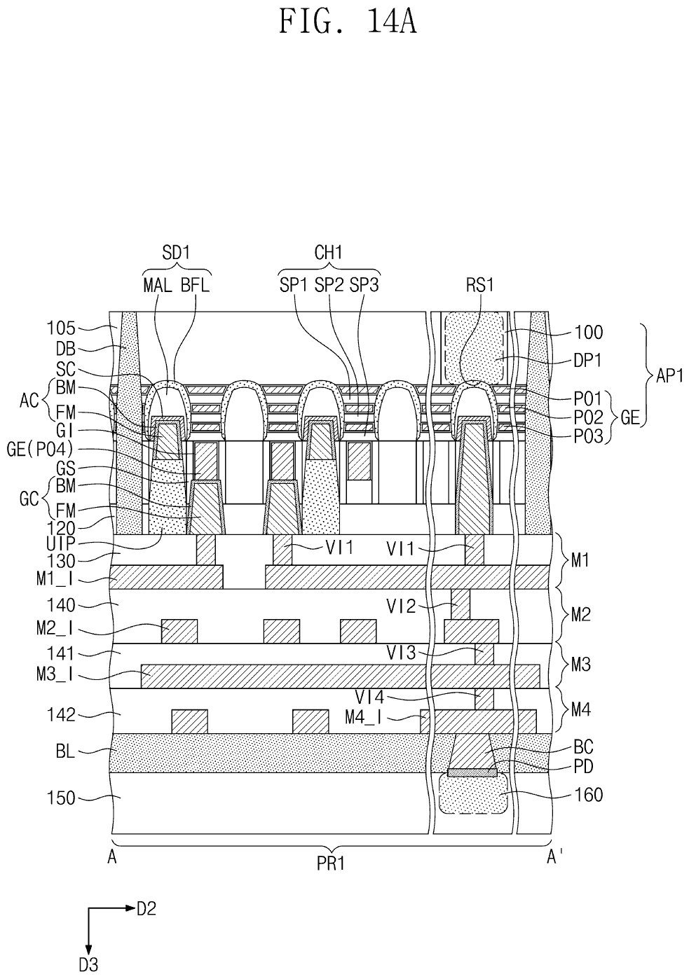

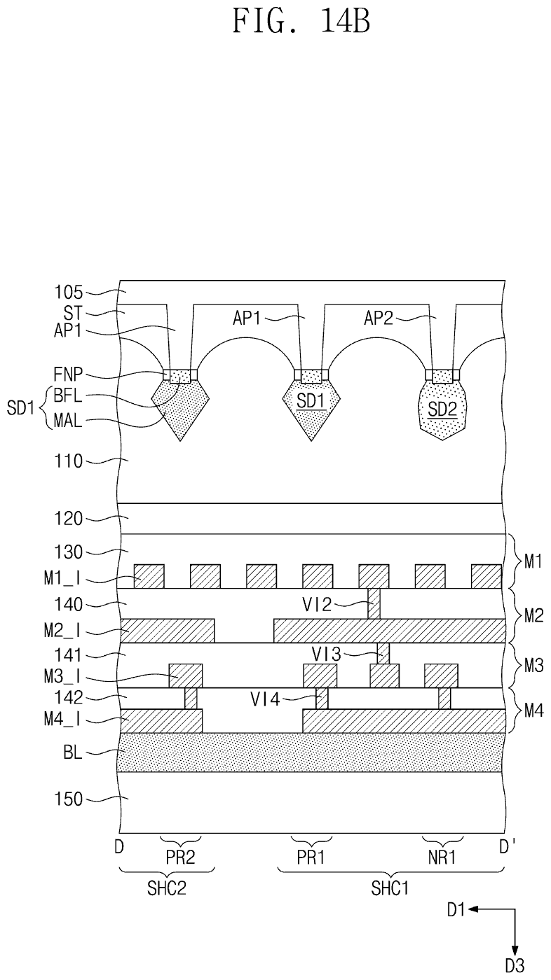

Referring to FIGS. 14A and 14B, the first substrate 105 may be formed by at least partially filling an empty region, which is formed by the removal of the semiconductor substrate 100, with an insulating material. The first substrate 105 may include a silicon-based insulating layer. The first substrate 105 may include the first insulating pattern AP1 filling at least a portion of the first backside trench TRV1. The first substrate 105 may include the second insulating pattern AP2 filling at least a portion of the second backside trench TRV2.

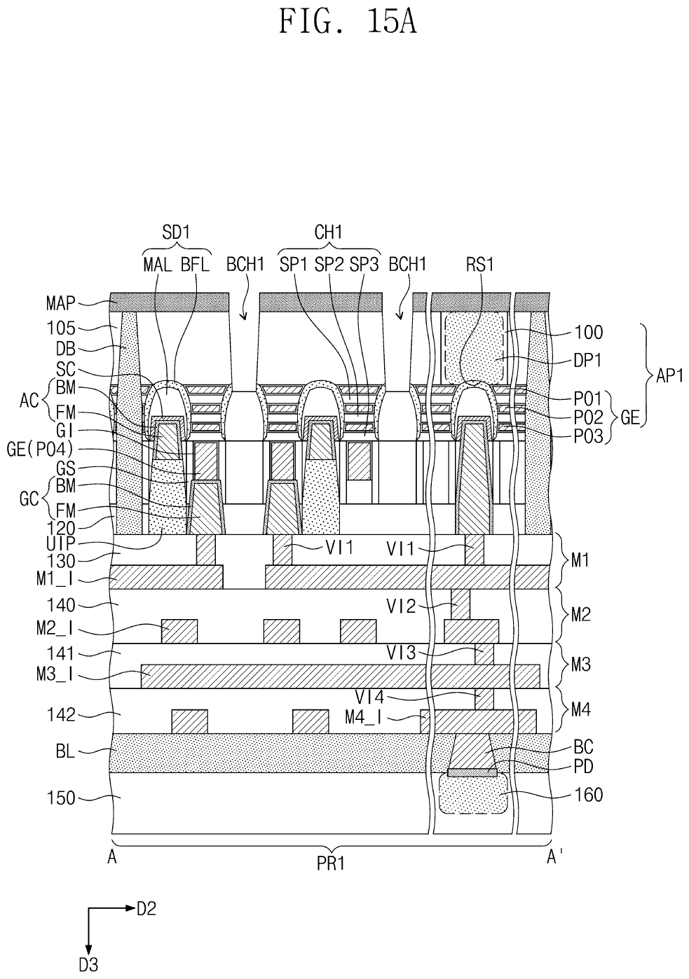

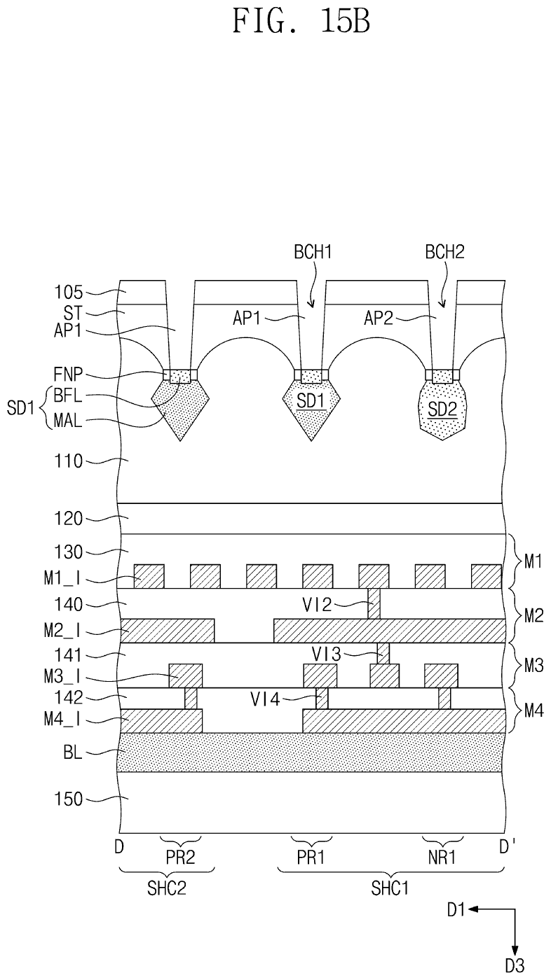

Referring to FIGS. 15A and 15B, the mask pattern MAP may be formed on the first substrate 105. The mask pattern MAP may be formed through a photolithography process. An anisotropic etching process using the mask pattern MAP as an etch mask may be performed on the first substrate 105 to form first and second backside contact holes BCH1 and BCH2. The first backside contact hole BCH1 may be formed to expose the first source/drain pattern SD1. The second backside contact hole BCH2 may be formed to expose the second source/drain pattern SD2.

Referring back to FIGS. 5A to 5F, the mask pattern MAP may be selectively removed. The backside contact BAC may be formed by filling at least a portion of the first and second backside contact holes BCH1 and BCH2 with a metallic material.

The lower substrate 107 may be formed on the bottom surfaces of the first substrate 105 and the second substrate 100. The backside via BVI may be formed in the lower substrate 107. The formation of the backside via BVI may include forming a mask pattern on a bottom surface of the lower substrate 107, etching the lower substrate 107 using the mask pattern as an etch mask to form a backside via hole, and filling at least a portion of the backside via hole with a metallic material.

The lower power lines VPR1 to VPR3 may be formed on the lower substrate 107. The lower power lines VPR1 to VPR3 may be connected to at least one of the backside vias BVI. The power delivery network layer PDN may be formed on the lower power lines VPR1 to VPR3. The power delivery network layer PDN may be configured to apply a source voltage or a drain voltage to the lower power lines VPR1 to VPR3.

According to an embodiment of the present disclosure, a protection structure including a source/drain pattern and a doping pattern may be provided on a substrate. The doping pattern may be connected to a lower power line, and the source/drain pattern may be connected to a metal layer on the substrate through an active contact. A sustain substrate including an impurity region may be provided on the metal layer. Accordingly, plasma and heat, which is generated in a backside process, may be exhausted or dissipated to the impurity region of the sustain substrate through the protection structure and the metal layer. As a result, the electrical and reliability characteristics of the semiconductor device may be improved.

While example embodiments of the present disclosure have been particularly shown and described, it will be understood by one of ordinary skill in the art that variations in form and detail may be made therein without departing from the scope of the attached claims.

What is claimed is:

1. A semiconductor device, comprising:
a substrate;
a lower power line in a lower portion of the substrate;
metal layers on the substrate; and
a protection structure that is electrically connected to the lower power line and the metal layers,
wherein the protection structure comprises:
a doping pattern in the substrate; and
a first source/drain pattern that is on the substrate and is electrically connected to an upper portion of the doping pattern, and
wherein the doping pattern and the first source/drain pattern comprise different dopants from each other.

2. The semiconductor device of claim 1, wherein the semiconductor device further comprises:
a bonding layer on an uppermost metal layer of the metal layers; and
a second substrate on the bonding layer,
wherein the second substrate comprises an impurity region in a lower portion of the second substrate.

3. The semiconductor device of claim 2, further comprising a bonding contact in the bonding layer, wherein the bonding contact electrically connects the uppermost metal layer to the impurity region of the second substrate.

4. The semiconductor device of claim 3, further comprising at least one of a metal pad or a silicide pad between the bonding contact and the impurity region of the second substrate.

5. The semiconductor device of claim 1, further comprising an active contact that electrically connects the first source/drain pattern to the metal layers.

6. The semiconductor device of claim 1, further comprising a backside via that electrically connects the doping pattern to the lower power line.

7. The semiconductor device of claim 1, further comprising:
a second source/drain pattern adjacent to the first source/drain pattern; and
a backside contact that extends into the substrate and electrically connects the lower power line to the second source/drain pattern.

8. The semiconductor device of claim 7, wherein:
the substrate comprises a first substrate and a second substrate,
the first substrate comprises the backside contact,
the second substrate comprises the doping pattern, and
the first substrate and the second substrate comprise different materials.

9. The semiconductor device of claim 1, wherein the first source/drain pattern and the doping pattern comprise different impurity types.

10. A semiconductor device, comprising:
a first substrate that comprises a first insulating pattern and a second insulating pattern;
a lower power line in a lower portion of the first substrate;
metal layers on the first substrate; and
a first protection structure on the first insulating pattern and a second protection structure on the second insulating pattern,
wherein the first protection structure and second protection structure are electrically connected to the lower power line and the metal layers,
wherein the first protection structure comprises a first doping pattern in the first insulating pattern and a first source/drain pattern on the first doping pattern,
wherein the second protection structure comprises a second doping pattern in the second insulating pattern and a second source/drain pattern on the second doping pattern, and
wherein the first and second doping patterns have different conductivity types from each other.

11. The semiconductor device of claim 10, wherein the first doping pattern and the second doping pattern comprise different impurity types.

12. The semiconductor device of claim 10, further comprising a first backside via and a second backside via electrically connecting the first doping pattern and the second doping pattern, respectively, to the lower power line.

13. The semiconductor device of claim 10, wherein:
the first doping pattern and the second source/drain pattern comprise a first conductivity type impurity, and
the second doping pattern and the first source/drain pattern comprise a second conductivity type impurity.

14. The semiconductor device of claim 10, further comprising a second substrate on the metal layers, wherein the second substrate comprises an impurity region.

15. The semiconductor device of claim 14, further comprising a bonding layer between the metal layer and the second substrate, wherein the bonding layer further comprises a bonding contact that electrically connects the metal layers to the impurity region.

16. A semiconductor device, comprising:
a first substrate that comprises a first region and a second region;
a channel pattern that is on a first surface of the first substrate and on the first region, wherein the channel pattern comprises a plurality of semiconductor patterns that are spaced apart from each other in a first direction that is perpendicular to an upper surface of the first substrate;
a first source/drain pattern electrically connected to the channel pattern;
a doping pattern on the second region;
a second source/drain pattern on the doping pattern;
a gate electrode on the channel pattern;
a gate insulating layer between the gate electrode and the channel pattern;
a gate spacer on a side surface of the gate electrode;
a gate capping pattern on a top surface of the gate electrode;
an interlayer insulating layer on the first source/drain pattern, the second source/drain pattern, and the gate capping pattern;
a gate contact that extends into the interlayer insulating layer and the gate capping pattern and is electrically connected to the gate electrode;
an active contact that extends into the interlayer insulating layer and is electrically connected to the second source/drain pattern;
a plurality of metal layers on the interlayer insulating layer, wherein each of the plurality of metal layers comprises interconnection lines and vias;
a second substrate that is on the plurality of metal layers and comprises an impurity region;
a lower power line on a second surface of the first substrate that is opposite to the first surface of the first substrate; and
a backside contact that extends into the first region and electrically connects the lower power line to the first source/drain pattern,
wherein the second source/drain pattern is electrically connected to the impurity region of the second substrate by the active contact and the plurality of metal layers.

17. The semiconductor device of claim 16, further comprising a bonding layer between an uppermost metal layer of the plurality of metal layers and the second substrate, wherein the bonding layer further comprises a bonding contact that electrically connects the uppermost metal layer to the impurity region.

18. The semiconductor device of claim 16, further comprising a backside via that electrically connects the doping pattern to the lower power line.

19. The semiconductor device of claim 18, wherein the second source/drain pattern is electrically connected to the lower power line by the doping pattern and the backside via.

20. The semiconductor device of claim 16, wherein the second source/drain pattern and the doping pattern comprise different impurities from each other.
